(19) United States
(12) Patent Application Publication
(10) Pub. No.: US 2017/0012108 A1
(43) Pub. Date: Jan. 12, 2017

(54) METHOD FOR MANUFACTURING SEMICONDUCTOR DEVICE

(71) Applicants: DENSO CORPORATION, Kariya-city (JP); TOYOTA JIDOSHA KABUSHIKI KAISHA, Toyota-shi (JP)

(72) Inventors: Jun SAKAKIBARA, Kariya-city (JP); Nozomu AKAGI, Kariya-city (JP); Shoji MIZUNO, Kariya-city (JP); Yuichi TAKEUCHI, Kariya-city (JP); Katsumi SUZUKI, Nagakute-city (JP)

(21) Appl. No.: 15/113,475

(22) PCT Filed: Jan. 14, 2015
(86) PCT No.: PCT/JP2015/000123

§ 371 Date: Jul. 22, 2016

(30) Foreign Application Priority Data
Jan. 24, 2014 (JP) 2014-011643
Dec. 5, 2014 (JP) 2014-246956

(51) Int. Cl. H01L 29/66; H01L 29/78; H01L 29/08; H01L 21/02; H01L 23/544; H01L 29/16; H01L 29/10

(52) U.S. Cl. CPC H01L 29/66068; H01L 29/1608; H01L 29/7813; H01L 29/1095; H01L 21/02634; H01L 21/02529; H01L 23/544; H01L 29/0865; H01L 21/0243; H01L 21/0262; H01L 2223/54426

(57) ABSTRACT

In a method for manufacturing a semiconductor device, when a second conductive type impurity layer is formed to provide a deep layer having a second conductive type in a first concavity and to provide a channel layer having the second conductive type on a surface of a drift layer, an epitaxial growth is performed under a growth condition that a contact trench provided by a recess is formed on a surface of a part of the second conductive type impurity layer corresponding to a center position of the first concavity, and a contact region is formed by ion-implanting a second conductive type impurity on a bottom of the contact trench.

### CROSS REFERENCE TO RELATED APPLICATIONS

This application is based on Japanese Patent Applications No. 2014-11643 filed on Jan. 24, 2014, and No. 2014-246956 filed on Dec. 5, 2014, the disclosures of which are incorporated herein by reference.

### TECHNICAL FIELD

The present disclosure relates to a method for manufacturing a semiconductor device having a trench gate.

### BACKGROUND ART

Conventionally, to reduce an on-state resistance in a vertical MOSFET, a pitch of cell is narrowed, and therefore, a density of a channel is increased. This type of the vertical MOSFET having a trench gate structure is proposed. In the vertical MOSFET having the trench gate structure, the channel is formed on a sidewall of the trench gate, so that the channel is formed along a normal line of a surface of a semiconductor substrate. Accordingly, a pitch of the cell in the vertical MOSFET having the trench gate structure is narrower than a vertical MOSFET having a planar structure, in which the channel is formed to be in parallel to the surface of the semiconductor substrate. However, in the vertical MOSFET, a source electrode is formed on a surface side of the semiconductor substrate through a contact hole, which is formed in an interlayer insulation film. Thus, it is necessary to provide a contact area, and therefore, there is a limit for narrowing the pitch.

Further, in the MOSFET having the trench gate structure, a technical object arises such that an electric field concentration is generated on a bottom of the trench in the trench gate structure. To reduce the electric field concentration, a deep layer is formed to be deeper than the bottom of the trench. In such an electric field relaxation structure, when the deep layer is designed, a distance between the trench and the deep layer and a protrusion amount from the trench are main design parameters. However, when the pitch of the cell is narrowed, it is difficult to secure a positioning accuracy among the trench, the deep layer and the interlayer insulation film. Specifically, in a silicon device, when the deep layer is formed by an ion implantation method of an impurity and a thermal diffusion method of the impurity, the range of the deep layer is expanded because of the thermal diffusion. Thus, it is necessary to create a margin. Thus, it is difficult to narrow the pitch of the cell.

In order to achieve the above object, for example, Patent literature No. 1 teaches a vertical MOSFET. In the vertical MOSFET, a trench is formed in a N type drift layer. A P type deep layer is epitaxially grown in the trench. Thus, the electric field concentration on the bottom of the trench is restricted. Further, it is not necessary to create the margin of the expansion of the P type deep layer caused by the thermal diffusion. Further, the trench is formed in a contact portion in the semiconductor layer, which is electrically connected to the source electrode, and the source electrode is embedded in the trench. Thus, a contact area between the source electrode and the semiconductor layer is increased, and the pitch is narrower, compared with a case where the contact portion is flat.

### PRIOR ART LITERATURES

### Patent Literature

Patent Literature 1: JP-2009-260253-A

### SUMMARY OF INVENTION

### Object to be Achieved by the Invention

However, in the vertical MOSFET disclosed in the Patent Literature No. 1, it is necessary to provide an etching step for forming the trench in the contact portion. Thus, a technical object arises such that the number of steps for manufacturing increases.

Specifically, the vertical MOSFET disclosed in the Patent Literature No. 1 is manufactured by the following manufacturing method.

First, the N type drift layer is formed on the N type semiconductor substrate. After that, the trench is formed at a P-type-deep-layer to-be-formed place in the N type drift layer. Then, the P type layer is deposited so as to fill the trench. Then, the P type layer is flattened until the N type drift layer is exposed. Thus, the surface of the P type layer and the surface of the N type drift layer are flat, and the P type layer provides the P type deep layer. Then, the P type channel layer is formed on the P type deep layer and the N type drift layer. Further, the N type source region is formed on the P type channel layer.

Further, the N type source region and the P type channel layer above the P type deep layer are etched, so that the trench for providing the contact portion is formed. After that, another trench for forming the trench gate structure is formed at a position different from the trench for providing the contact portion. Then, the inner wall of the trench is covered with a gate insulation film. Further, the gate electrode is formed on the gate insulation film. Then, the interlayer insulation film is formed, and the contact hole is formed in the interlayer insulation film. Then, the source electrode is formed so as to connect to the N type source region and the P type deep layer through the contact hole. Finally, the drain electrode is formed on the back side of the N type semiconductor substrate. Thus, the vertical MOSFET is manufactured.

In the above manufacturing process, in order to form the trench in the contact portion, the N type source region and the P type channel layer above the P type deep layer are etched. Accordingly, as described above, the number of steps in the manufacturing process increases.

In view of the above points, it is an object of the present disclosure to provide a method for manufacturing a semiconductor device having a vertical MOSFET, in which a deep layer is formed to relax an electric field on the bottom of a trench for providing a trench gate structure, and a trench is formed in a contact portion so that a pitch of a cell is narrowed, without performing an etching step for forming the trench in the contact portion.

### Means for Achieving Object

According to an aspect of the present disclosure, in a method for manufacturing a semiconductor device, a drift layer having a first conductive type with an impurity concentration lower than a semiconductor substrate is formed on the semiconductor substrate having the first conductive type or a second conductive type. After a mask is arranged on a surface of the drift layer, a plurality of first concavities is formed to be separated from each other on a cross section in parallel to a surface of the semiconductor substrate by removing a part of the drift layer in an etching process using the mask. After the mask is removed, a second conductive type impurity layer for providing a plurality of deep layers having the second conductive type in the plurality of first concavities and for providing a channel layer having the second conductive type on the surface of the drift layer is formed. A trench gate structure is formed by forming a trench between the plurality of deep layers to penetrate the channel layer from a surface of the second conductive type impurity layer, to reach the drift layer and to be shallower than the plurality of deep layers, by forming a gate insulation film on an inner surface of the trench, and by forming a gate electrode on the gate insulation film in the trench. A source region having the first conductive type with a concentration higher than the drift layer is formed by ion-implanting a first conductive type impurity in a surface portion of the channel layer. A contact region having the second conductive type with a concentration higher than the channel layer is formed by ion-implanting a second conductive type impurity in a surface portion of the channel layer corresponding to a center position of each first concavity. A source electrode electrically connected to the source region and the contact region is formed. A drain electrode is formed on a back side of the semiconductor substrate.

In the forming of the second conductive type impurity layer, an epitaxial growth is performed under a growth condition that a contact trench provided by a recess is formed on a surface of a part of the second conductive type impurity layer corresponding to the center position of each first concavity. In the forming of the contact region, the contact region is formed on a bottom of the contact trench.

In the above method for manufacturing the semiconductor device, when the second conductive type impurity layer is formed, the recess remains on the part of the second conductive type impurity layer corresponding to the center position of each first concavity. The recess provides the contact trench. Accordingly, it is not necessary to perform an etching process for forming the contact trench. Thus, the number of steps of the manufacturing process is not increased. In addition, the contact trench is formed by a self-alignment of the deep layer.

### BRIEF DESCRIPTION OF DRAWINGS

The above and other objects, features and advantages of the present disclosure will become more apparent from the following detailed description made with reference to the accompanying drawings. In the drawings:

FIG. 1 is a cross sectional view of a SiC semiconductor device having an inversion type vertical MOSFET with a trench gate structure according to a first embodiment of the present disclosure;

FIG. 2A is a cross sectional view showing a part of the manufacturing process of the SiC semiconductor device shown in FIG. 1;

FIG. 2B is a cross sectional view showing the part of the manufacturing process of the SiC semiconductor device next to FIG. 2A;

FIG. 2C is a cross sectional view showing the part of the manufacturing process of the SiC semiconductor device next to FIG. 2B;

FIG. 2D is a cross sectional view showing the part of the manufacturing process of the SiC semiconductor device next to FIG. 2C;

FIG. 2E is a cross sectional view showing the part of the manufacturing process of the SiC semiconductor device next to FIG. 2D;

FIG. 2F is a cross sectional view showing the part of the manufacturing process of the SiC semiconductor device next to FIG. 2E;

FIG. 2G is a cross sectional view showing the part of the manufacturing process of the SiC semiconductor device next to FIG. 2F;

FIG. 3 is a cross sectional view of a SiC semiconductor device having an inversion type vertical MOSFET with a trench gate structure according to a second embodiment of the present disclosure;

FIG. 4A is a cross sectional view showing a part of the manufacturing process of the SiC semiconductor device shown in FIG. 3;

FIG. 4B is a cross sectional view showing the part of the manufacturing process of the SiC semiconductor device next to FIG. 4A;

FIG. 4C is a cross sectional view showing the part of the manufacturing process of the SiC semiconductor device next to FIG. 4B;

FIG. 4D is a cross sectional view showing the part of the manufacturing process of the SiC semiconductor device next to FIG. 4C;

FIG. 4E is a cross sectional view showing the part of the manufacturing process of the SiC semiconductor device next to FIG. 4D;

FIG. 4F is a cross sectional view showing the part of the manufacturing process of the SiC semiconductor device next to FIG. 4E;

FIG. 4G is a cross sectional view showing the part of the manufacturing process of the SiC semiconductor device next to FIG. 4F;

FIG. 4H is a cross sectional view showing the part of the manufacturing process of the SiC semiconductor device next to FIG. 4G;

FIG. 5A is a cross sectional view showing a part of the manufacturing process of a SiC semiconductor device having an inversion type vertical MOSFET with a trench gate structure according to a third embodiment of the present disclosure;

FIG. 5B is a cross sectional view showing the part of the manufacturing process of the SiC semiconductor device next to FIG. 5A;

FIG. 5C is a cross sectional view showing the part of the manufacturing process of the SiC semiconductor device next to FIG. 5B;

FIG. 5D is a cross sectional view showing the part of the manufacturing process of the SiC semiconductor device next to FIG. 5C;

FIG. 6 is a cross sectional view of a SiC semiconductor device having an inversion type vertical MOSFET with a trench gate structure according to a fourth embodiment of the present disclosure;

FIG. 7 is a cross sectional view of a SiC semiconductor device having an inversion type vertical MOSFET with a trench gate structure according to a fifth embodiment of the present disclosure; and

FIG. 8 is a cross sectional view of a SiC semiconductor device having an inversion type vertical MOSFET with a trench gate structure according to a sixth embodiment of the present disclosure;

### EMBODIMENTS FOR CARRYING OUT INVENTION

Embodiments of the present disclosure will be explained with reference to drawings. Here, the same part or an equivalent part in each embodiment will be explained with using the same reference numeral.

### First Embodiment

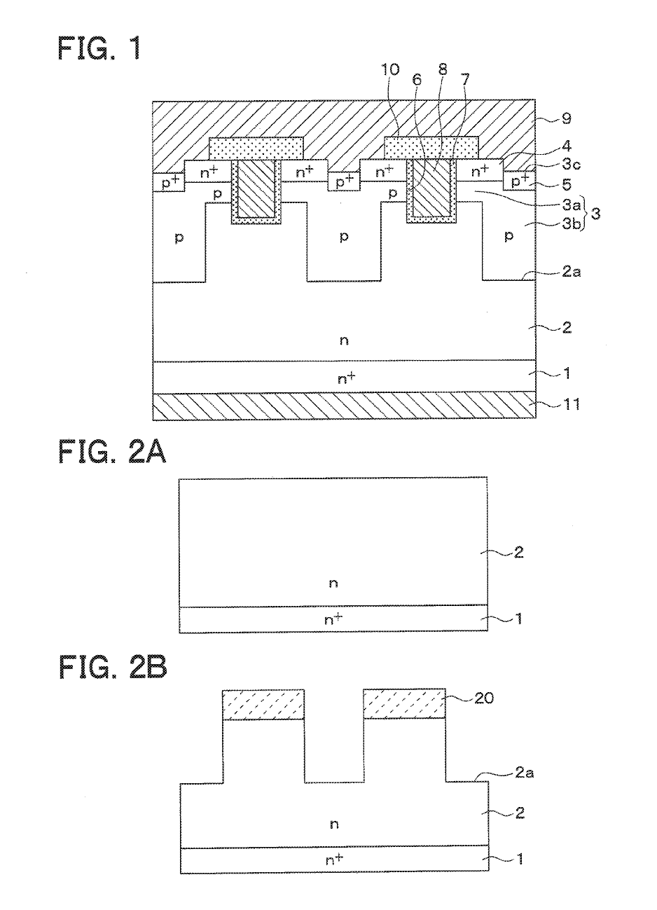

A first embodiment of the present disclosure will be explained. First, a structure of a SiC semiconductor device having an inversion type vertical MOSFET with a trench gate structure, which is manufactured by a manufacturing method according to the present embodiment, will be explained with reference to FIG. 1. Here, in FIG. 1, two cells of the vertical MOSFET are merely shown. Multiple cells having the same structure as the vertical MOSFET shown in FIG. 1 are arranged to be adjacent to each other.

As shown in FIG. 1, a N+ type semiconductor substrate 1 made of silicon carbide single crystal, in which a N type impurity (such as nitrogen) is highly doped, is used. A N type drift layer 2 made of SiC, in which the N type impurity is doped, is formed on the N+ type semiconductor substrate 1.

Further, a concavity (i.e., a first concavity) 2a is formed in the N type drift layer 2 by being partially concaved. A P type impurity layer 3 made of SiC is formed by doping a P type impurity in the surface of the N type drift layer 2 including an inner surface of the concavity 2a. Thus, a P type channel layer 3a and a P type deep layer 3b are formed. In the present embodiment, an impurity concentration in the P type impurity layer 3 is homogeneous ion a depth direction. For example, the impurity concentration is in a range between 1×10¹⁷ cm⁻³ and 1×10¹⁸ cm⁻³.

The P type channel layer 3a is a layer for providing a channel of the vertical MOSFET. The channel layer 3a is formed on both sides of a trench 6 so as to contact a sidewall of the trench 6, which provides a later-described trench gate structure.

The P type deep layer 3b is arranged on both sides of the trench 6 so as to be spaced apart from the sidewall of the trench 6. Further, the distance between the P type deep layer 3b and the sidewall of the trench 6 is designed in order to deplete the N type drift layer 2, which is disposed between the trench 6 and the P type deep layer 3b, as much as possible when a depletion layer is expanded, and further, in order to generate an electric field relaxation effect. The bottom of the P type deep layer 3b is deeper than the bottom of the trench 6, and is disposed to a position nearer the N+ type semiconductor substrate 1 than the bottom of the trench 6.

A contact trench 3c is formed on the surface of the P type channel layer 3a at a position corresponding to a center position of the P type deep layer 3b. the contact trench 3c according to the present embodiment is formed to be a shape having multiple surfaces including a bottom and a sidewall. The bottom of the trench 3c is a plane in parallel to the surface of the N+ type semiconductor substrate 1. The sidewall of the trench 3c is a plane perpendicular to the bottom. In the present embodiment, the contact trench 3c has a structure shallower than the trench 6, and further, shallower than the P type channel layer 3a.

A N+ type source region 4, in which the N type impurity is doped with high concentration, is formed in a surface portion of the P type channel layer 3a other than the contact trench 3c. A P+ type contact region 5, in which the P type impurity is doped with high concentration, is formed on the bottom of the contact trench 3c.

Further, the trench 6 is formed at a center position of the P type deep layer 3b, which is arranged adjacent to each other in a cross section in FIG. 1, and the trench 6 penetrates the P type channel layer 3a and the N+ type source region 4, reaches the N type drift layer 2, and is shallower than the P type deep layer 3b. The P type channel layer 3a and the N+ type source region 4 are arranged so as to contact the sidewall of the trench 6. The inner wall of the trench 6 is covered with a gate insulation film 7 made of, for example, an oxide film. A gate electrode 8 made of doped poly silicon is formed on the surface of the gate insulation film 7 and fills in the trench 6. Thus, the gate insulation film 7 and the gate electrode 8 in the trench 6 provide the trench gate structure.

Here, not shown in FIG. 1, the trench gate structure has a reed shape with a direction perpendicular to a sheet of the drawing as a longitudinal direction. Multiple trench gate structures are aligned in a stripe pattern along a right-left direction of the sheet of the drawing at equally spaced intervals. Thus, multiple cells are included in the structure.

Further, the source electrode 9 is formed on the surface of the N+ type source region 4 and the surface of the P+ type contact region 5. The source electrode 9 is made of multiple metals (for example, nickel and aluminum). Specifically, a part of the electrode 9 contacting the N+ type source region 4 is made of metal, which is capable of contacting N type SiC in an Ohmic contact manner. Another part of the electrode 9 connecting to the P type channel layer 3a through the P+ type contact region 5 is made of metal, which is capable of contacting P type SiC in an Ohmic contact manner. Here, the source electrode 9 is electrically isolated from a gate wiring, which is not shown in the drawing and electrically connected to the gate electrode 8 on the interlayer insulation film 10. Further, the source electrode 9 electrically contacts the N+ type source region 4 and the P+ type contact region 5 through the contact hole, which is formed in the interlayer insulation film 10.

Further, the drain electrode 11 is formed on the back side of the N+ type semiconductor substrate 1 to electrically connect to the n+ type semiconductor substrate 1. Thus, the above structure provides the inversion type vertical n channel type MOSFET having the trench gate structure.

The vertical MOSFET having the above structure flows current between the source electrode 9 and the drain electrode 11 when the gate voltage is applied to the gate electrode 8 so that a portion of the P type channel layer 3a contacting the sidewall of the trench 6 becomes an inversion channel.

On the other hand, when the gate voltage is not applied, a high voltage (for example, 1200 volts) is applied as a drain voltage. The SiC has an electric field breakdown strength near ten times higher than a silicon device. The electric field near ten times higher than the silicon device is applied to the gate insulation film 7 because of the influence of the above voltage. Thus, the electric field concentration may occur at the gate insulation film 7 (specifically, at a part of the gate insulation film 7 on the bottom of the trench 6). However, in the present embodiment, the structure has the P type deep layer 3b deeper than the trench 6. Accordingly, the depletion layer at the PN junction between the P type deep layer 3b and the N type drift layer 2 largely extends to the N type drift layer 2 side. Thus, the high voltage caused by the influence of the drain voltage is less likely to invade into the gate insulation film 7.

Accordingly, it is possible to reduce the electric field concentration in the gate insulation film 7, specifically, at the part of the gate insulation film 7 on the bottom of the trench 6. Thus, it is possible to restrict the breakdown of the gate insulation film 7.

The contact trench 3c is formed at the contact portion of the source electrode 9. The P+ type contact region 5 is formed on the bottom of the contact trench 3c. Thus, the source electrode 9 is electrically connected to the N+ type source region 4 and the P+ type contact region 5. Thus, the contact area between the source electrode 9 and the N+ type source region 4 or the P+ type contact region 5 is increased, compared with a case where the contact trench 3c is not formed. Thus, it is possible to narrow the pitch of the cells. Specifically, since the structure has the contact trench 3c with multiple surfaces, the contact area between the source electrode 9 and the N+ type source region 4 or the P+ type contact region 5 becomes wider, and therefore, it is possible to provide a low contact resistance.

When the vertical MOSFET functions in a diode operation or in an avalanche operation, the current flows in a wide area on the bottom having a planar shape. Accordingly, the current concentration is reduced, and it is possible to provide the vertical MOSFET with high breakdown tolerance.

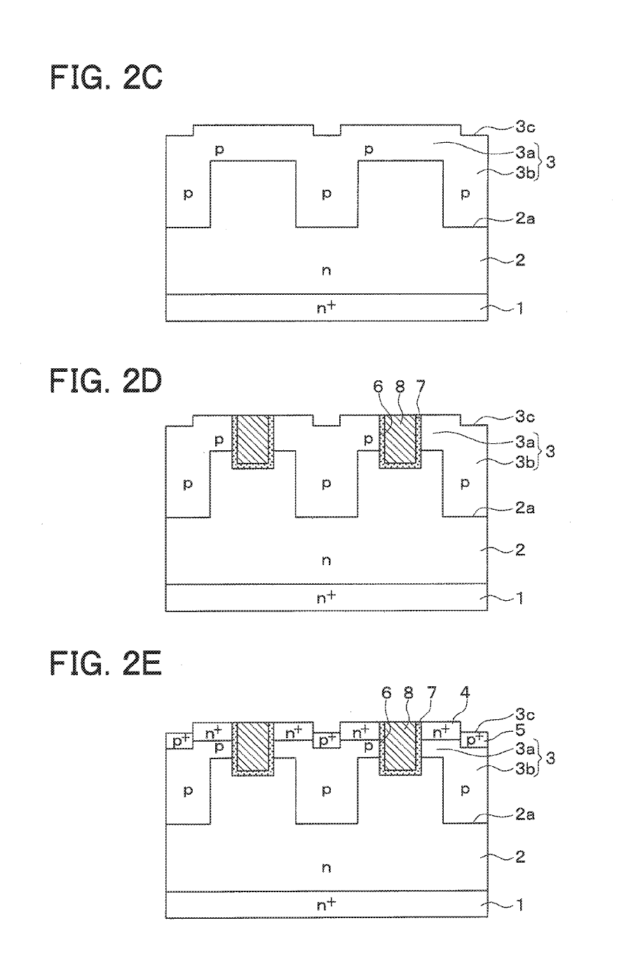

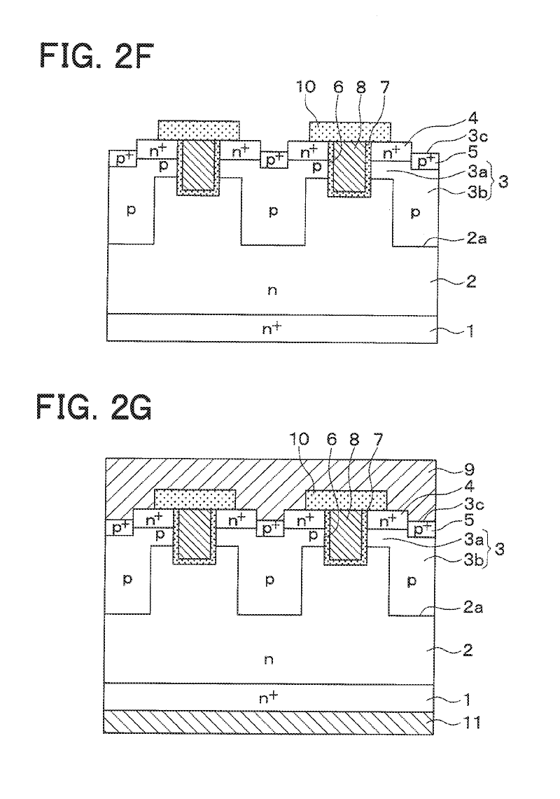

Next, the method for manufacturing the trench gate type vertical MOSFET shown in FIG. 1 will be explained with reference to FIGS. 2A to 2G.

At a step shown in FIG. 2A, firstly, an epitaxial substrate is prepared such that the N type drift layer 2 is epitaxially grown on the surface of the N+ type semiconductor substrate 1 made of SiC single crystal with the N type impurity highly doped.

At a step shown in FIG. 2B, mask material such as an oxide film is deposited on the N type drift layer 2. Then, the mask material is patterned, so that the mask 20 is formed to have an opening at a P-type-deep-layer-3b to-be-formed region, i.e., at a concavity-2a to-be-formed region. Using the mask 20, an anisotropic etching process such as a reactive ion etching (i.e., RIE) process is performed. Thus, the surface portion of the N type drift layer 2 is removed through the opening of the mask 20, so that the concavity 2a is formed. The depth and the width of the concavity 2a are designed in view of thermal diffusion in each step performed later so that the finished depth and the finished width of the P type deep layer 3b become desired values.

At a step shown in FIG. 2C, after the mask 20 used for the formation of the concavity 2a is removed, the P type impurity layer 3 for providing the P type channel layer 3a and the P type deep layer 3b is epitaxially grown on the surface of the N type drift layer 2 including the inside of the concavity 2a. For example, using a chemical vapor deposition (i.e., CVD) apparatus, silane (i.e., SiH₄) gas and propane (C₃H₈) gas are introduced into atmosphere simultaneously, and further, gas including a dopant is introduced into the mixed gas. Thus, the epitaxial growth is performed, so that the P type impurity layer 3 is formed. At this time, a recess remains at the center of the surface of a part of the P type impurity layer 3 formed in the concavity 2a, and the contact trench 3c is provided by the recess.

For example, the growth rate of the P type impurity layer 3 depends on a plane orientation. The dependency on the plane orientation is changed with growth parameters such as a growth temperature, a gas flow amount, and an atmosphere pressure in the epitaxial growth process. Accordingly, the plane orientation dependency, i.e., a ratio between a vertical direction growth rate of the P type impurity layer 3 formed on the surface of the N type drift layer 2 other than the concavity 2a and the bottom of the concavity 2a and a horizontal direction growth rate of the P type impurity layer 3 formed on the sidewall of the concavity 2a, is controlled based on the growth parameters. Thus, the depth and the width of the concavity 2a and the growth parameters are adjusted, so that the vertical direction growth rate of the P type impurity layer 3 becomes larger than the horizontal direction growth rate of the P type impurity layer 3. Thus, the contact trench 3c is formed on the surface of the P type impurity layer 3.

Further, at this time, the width of the contact trench 3c in an alignment direction of multiple P type deep layers 3b, i.e., the distance between both sidewalls, is smaller than the width of the P type deep layer 3b in the same direction. Specifically, in the vertical MOSFET according to the present embodiment, the length of the P type channel layer 3a between the trench 6 and the P type deep layer 3b is shortened, so that the electric field relaxation effect is effectively obtained. Thus, when designing the device, it is preferable to design the device with focusing on the length of the P type channel layer 3a. However, when the width of the contact trench 3c is larger than the width of the P type deep layer 3b in the same direction, the distance between the trench 6 and the contact trench 3c is shorter than the length of the P type channel layer 3a between the trench 6 and the P type deep layer 3b. In this case, the manufacturing process is limited by the distance between the trench 6 and the contact trench 3c. Thus, it is difficult to design the device with focusing on the length of the P type channel layer 3a.

Accordingly, in the present embodiment, the width of the contact trench 3c is set to be smaller than the width of the P type deep layer 3b in the same direction, so that the manufacturing process is not limited by the distance between the trench 6 and the contact trench 3c. Accordingly, it is possible to design the device with focusing on the length of the P type channel layer 3a.

Further, in the present embodiment, the contact trench 3c is shallower than the trench 6, and further, the contact trench 3c is shallower than the P type channel layer 3a. When the contact trench 3c is deep, the contact trench 3c is formed by the etching method. In this case, in order to deepen the contact trench 3c stably, it is necessary to restrict the aspect ratio to be a certain ratio. Accordingly, it is necessary to have a certain trench width, and therefore, the micro-fabrication is limited. Accordingly, in the present embodiment, the contact trench 3c is shallow, so that the micro-fabrication is achieved.

At a step shown in FIG. 2D, an etching mask not shown is formed to cover the P type impurity layer 3 and to have an opening at the trench-6 to-be-formed region. After the anisotropic etching process using the etching mask is performed, the isotropic etching process and a sacrifice oxidation process are performed if necessary, so that the trench 6 is formed. Thus, the trench 6 is formed to be shallower than the P type deep layer 3b and to be separated from the P type deep layer 3b between adjacent P type deep layers 3b.

Next, after the etching mask 21 is removed, the gate oxidation process is performed, so that the gate insulation film 7 is formed. After the poly crystal silicon layer, in which the impurity is doped, is deposited on the surface of the gate insulation film 7, the poly crystal silicon layer is patterned, so that the gate electrode 8 is formed. Thus, the trench gate structure is formed.

At a step shown in FIG. 2E, a mask (not shown) is formed on the surface of the P type impurity layer 3 to have an opening at the N+-type-source-region-4 to-be-formed region. Then, the N type impurity is ion-implanted over the mask with high concentration, so that the N+ type source region 4 is formed. Similarly, a mask (not shown) is formed on the surface of the P type impurity layer 3 to have an opening at the P+-type-contact-region-5 to-be-formed region. Then, the P type impurity is ion-implanted over the mask with high concentration, so that the P+ type contact region 5 is formed.

At a step shown in FIG. 2F, the interlayer insulation film 10 is deposited, and then, the interlayer insulation film 10 is patterned, so that the contact hole is formed to expose the N+ type source region 4 and the P type impurity layer 3. Further, the contact hole for exposing the gate electrode 8 is formed on a different cross section.

At a step shown in FIG. 2G, an electrode material is deposited to fill the contact hole, and the electrode material is patterned, so that the source electrode 9 and the gate wiring not shown are formed. Then, the drain electrode 11 is formed on the back side of the N+ type semiconductor substrate 1. Thus, the vertical MOSFET shown in FIG. 1 is completed.

As described above, in the present embodiment, when the P type impurity layer 3 is formed, the recess remains at the center of the part of the P type impurity layer 3 formed in the concavity 2a. Further, the contact trench 3c is provided by the recess. Accordingly, it is not necessary to perform the etching process for forming the contact trench 3c, so that the number of steps for the manufacturing process is not increased. In addition, the contact trench 3c is formed by a self-alignment of the P type deep layer 3b.

### Second Embodiment

A second embodiment of the present disclosure will be explained. In the present embodiment, the formation step of the P type impurity layer 3 is changed from the first embodiment. Other steps are similar to the first embodiment. A different part from the first embodiment will be explained.

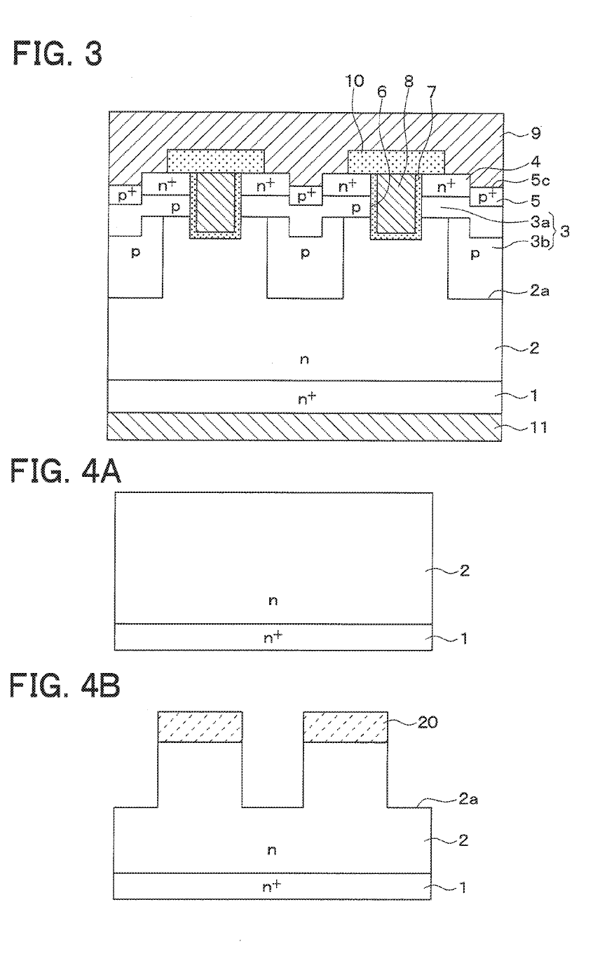

In the above first embodiment, the P type channel layer 3a and the P type deep layer 3b are formed simultaneously. In the present embodiment, as shown in FIG. 3, the P type channel layer 3a and the P type deep layer 3b are formed independently, so that the impurity concentration of the P type channel layer 3a is different from the P type deep layer 3b. Specifically, in the present embodiment, the vertical MOSFET having the trench gate structure shown in FIG. 3 is manufactured by the following manufacturing method.

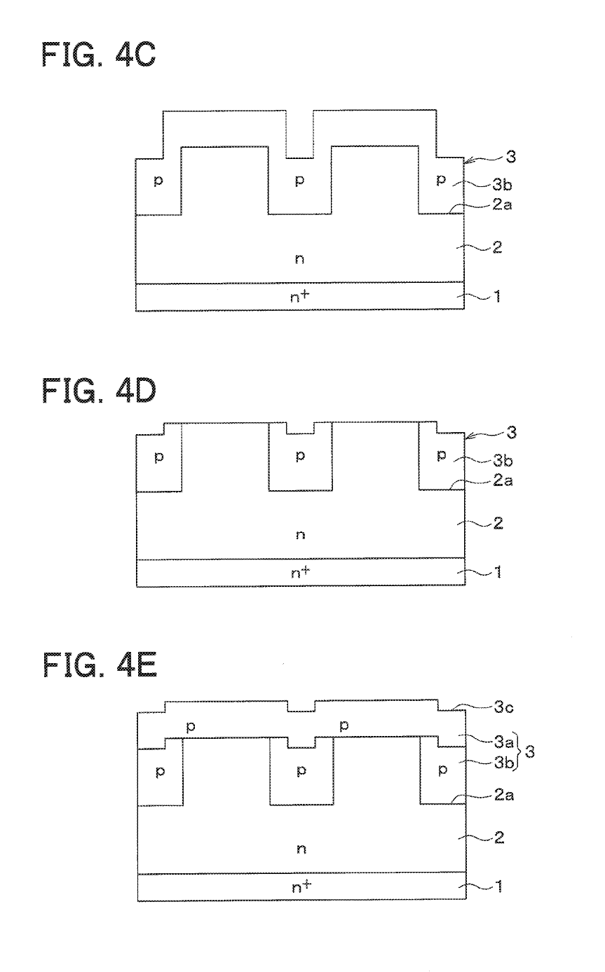

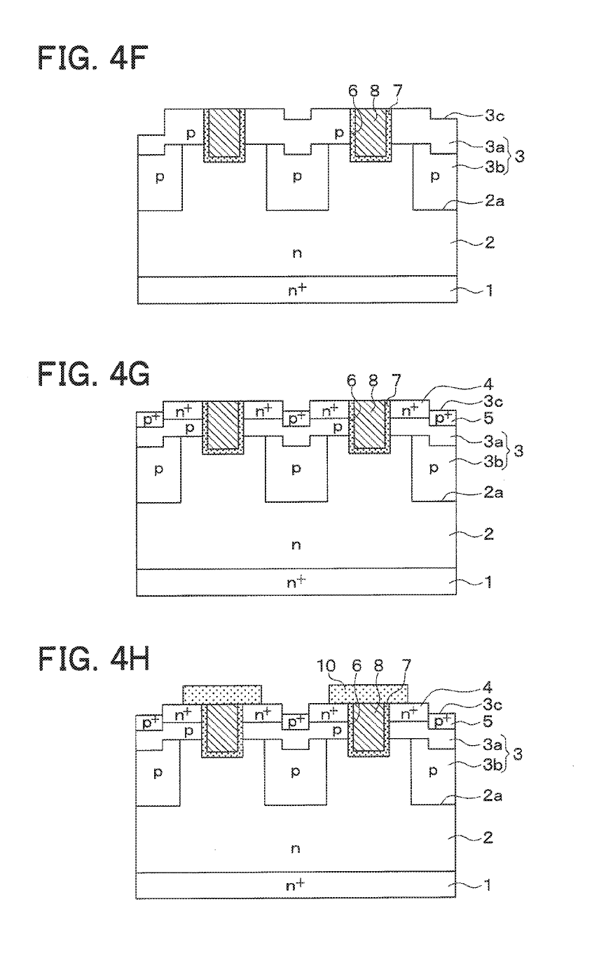

First, steps shown in FIGS. 4A to 4C are performed similar to the steps shown in FIGS. 2A to 2C. Here, at the step shown in FIG. 4C, only the part of the P type impurity layer 3 for providing the P type deep layer 3b is formed, and the recess remains at the center of the concavity 2a on the P type deep layer 2b. The bottom of the recess is positioned deeper than the surface of the N type drift layer 2 (i.e., at a position on the N+ type semiconductor substrate 1 side).

Then, at step shown in FIG. 4D, for example, a chemical mechanical polishing (i.e., CMP) process is performed so that the part of the P type deep layer 3b formed on the surface of the N type drift layer 2 is removed, and the surface of the N type drift layer 2 is exposed. In this case, as described above, the recess of the P type deep layer 3b remaining at the center of the concavity 2a is formed at a position deeper than the surface of the N type drift layer 2. Thus, the recess remains even when the surface of the N type drift layer 2 is exposed.

After that, at step shown in FIG. 4E, the P type channel layer 3a is epitaxially grown on the N type drift layer 2 and the P type deep layer 3b. In this case, since the recess remains in the P type deep layer 3b as a base, a recess remains at a position corresponding to the center of the concavity 2a on the P type channel layer 3a. The recess provides the contact trench 3c. After that, steps shown in FIGS. 4F to 4H are performed similar to FIGS. 2D, 2E and 2F described above. Further, although not shown in the drawing, a step similar to FIG. 2G is performed, so that the vertical MOSFET shown in FIG. 3 is completed.

As described above, the P type channel layer 3a and the P type deep layer 3b are formed by different steps. In this case, the impurity concentration of the P type channel layer 3a and the impurity concentration of the P type deep layer 3b are independently designed. Thus, the impurity concentration of the P type channel layer 3a is designed to be in a range between 1×10¹⁶ cm⁻³ and 1×10¹⁷ cm⁻³, which corresponds to a required threshold. The impurity concentration of the P type deep layer 3b is designed to be in a range between 1×10¹⁷ cm⁻³ and 1×10¹⁸ cm⁻³, which corresponds to a required breakdown.

### Third Embodiment

A third embodiment of the present disclosure will be explained. In the present embodiment, the formation step of the alignment mark is added to the first embodiment. Other steps are similar to the first embodiment. A different part from the first embodiment will be explained.

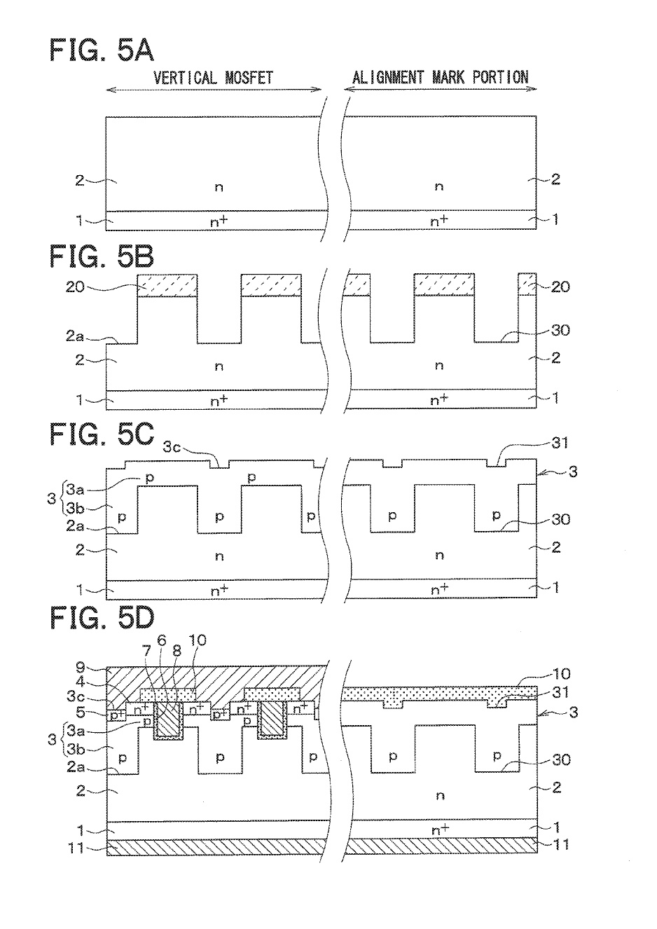

First, steps shown in FIGS. 5A to 5C are performed almost similar to the steps shown in FIGS. 2A to 2C.

In the above case, the alignment mark for aligning the mask is arranged in a scribe area, which is dicing-cut when the wafer is divided into each chip, or an unnecessary area, which is an outer periphery of a chip formation region. A concavity and a convexity in the alignment mark are used as a key for aligning the mask.

Specifically, at step shown in FIG. 5B, when the concavity 2a is formed, the concavity (i.e., a second concavity) 30 is also formed in the alignment mark simultaneously. Thus, when the P type impurity layer 3 is formed at the step shown in FIG. 5C, the recess remains in the alignment mark of the P type impurity layer 3, so that the recess provides the alignment mark 31. After that, the alignment mark 31 provides a standard for aligning the mask, and each step is performed. Then, as shown in FIG. 5D, each part of the vertical MOSFET is formed. Specifically, the formation step of the trench gate structure shown in FIG. 2D, the formation steps of the N+ type source region 4 and the P+ type contact region 5 shown in FIGS. 2E to 2G, the patterning step of the interlayer insulation film 10, the formation step of the source electrode 9, and the formation step of the drain electrode 11 are performed. Thus, it is possible to use the alignment mark 31 as the standard for aligning all masks. Thus, it is possible to minimize a deviation of each mask.

### Fourth Embodiment

A fourth embodiment of the present disclosure will be explained. In the present embodiment, a shape of the contact trench 3c for providing the P+ type contact region 5 is changed from the first embodiment. Other steps are similar to the first embodiment. A different part from the first embodiment will be explained.

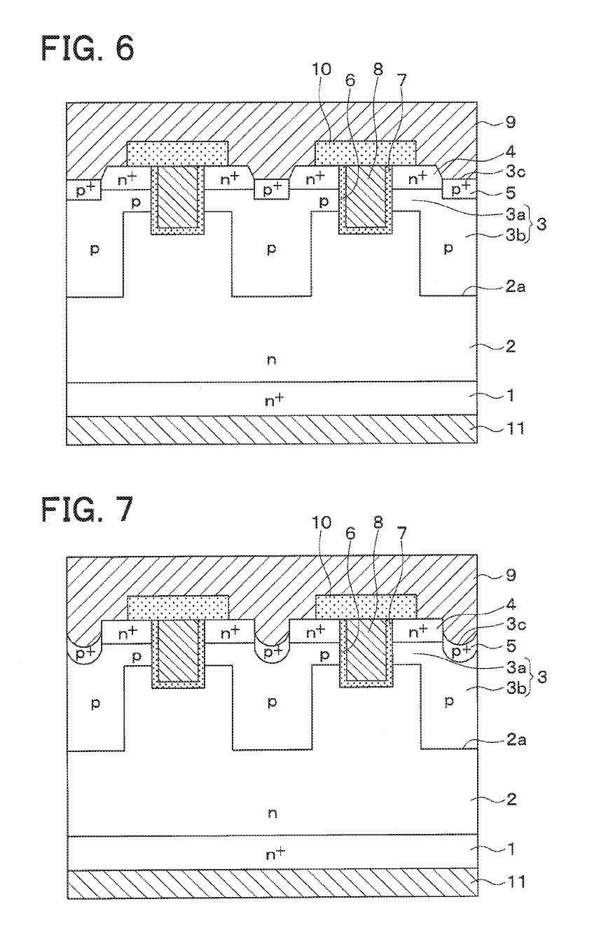

As shown in FIG. 6, in the present embodiment, the contact trench 3c has a structure with a bottom having a plane shape and a sidewall having a plane shape. The contact trench 3c further has a sidewall, which is a slant surface having a tapered shape so that opening dimensions of the contact trench 3c gradually increases toward the trench entrance from the bottom of the contact trench 3c.

Thus, even when the sidewall of the contact trench 3c is the slant surface having the tapered shape, the effects similar to the above described embodiments are obtained. Further, when the vertical MOSFET functions in a diode operation or in an avalanche operation, the current flows in a wide area on the bottom having a planar shape. Accordingly, the current concentration is reduced, and it is possible to provide the vertical MOSFET with high breakdown tolerance.

Here, when the mixture ratio of the silane gas and the propane gas, which are used for forming the P type channel layer 3a, i.e., a C/Si ratio is adjusted, the sidewall of the contact trench 3c becomes the slant surface.

### Fifth Embodiment

A fifth embodiment of the present disclosure will be explained. In the present embodiment, a shape of the contact trench 3c for providing the P+ type contact region 5 is changed from the first embodiment. Other steps are similar to the first embodiment. A different part from the first embodiment will be explained.

As shown in FIG. 7, in the present embodiment, the contact trench 3c has a structure with a bottom and a sidewall, and the bottom has a curved shape with a rounded bottom. Thus, the upper surface and the lower surface of the P+ type contact region 5 also have a curved shape with a rounded surface, similar to the bottom of the contact trench 3c.

Thus, even when the bottom of the contact trench 3c has the curved shape with a rounded bottom, the effects similar to the above described embodiments are obtained. Further, when the bottom is rounded, a boundary between the bottom and the sidewall is also rounded. Thus, when the vertical MOSFET functions in a diode operation or in an avalanche operation, the current concentration at the boundary between the bottom and the sidewall is reduced. Accordingly, it is possible to provide the vertical MOSFET with high breakdown tolerance.

Here, when the atmospheric temperature of the CVD apparatus is high (for example, 1600° C. or higher) while forming the P type channel layer 3a, the bottom of the contact trench 3c has a rounded shape.

### Sixth Embodiment

A sixth embodiment of the present disclosure will be explained. In the present embodiment, a shape of the contact trench 3c for providing the P+ type contact region 5 is changed from the first embodiment. Other steps are similar to the first embodiment. A different part from the first embodiment will be explained.

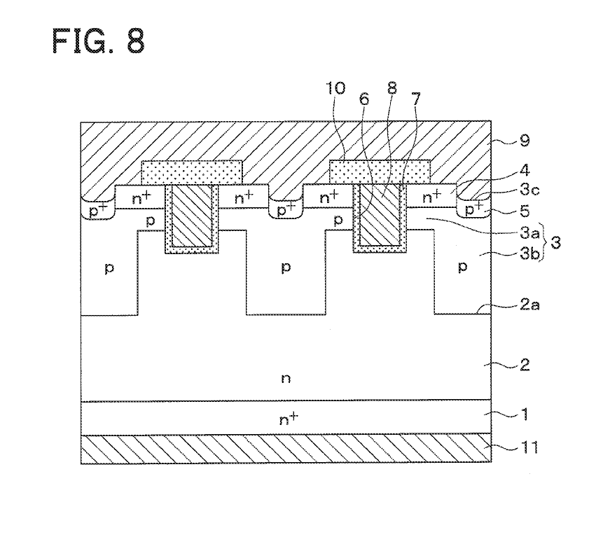

As shown in FIG. 8, in the present embodiment, the contact trench 3c has a structure with a bottom and a sidewall, and the boundary between the bottom and the sidewall has a curved shape with a rounded boundary. Thus, both edges of the upper surface and the lower surface of the P+ type contact region 5 in the right-left direction in FIG. 8 also have a curved shape with a rounded edge, similar to the boundary between the bottom and the sidewall of the contact trench 3c.

Thus, even when the boundary between the bottom and the sidewall of the contact trench 3c has the curved shape with a rounded boundary, the effects similar to the above described embodiments are obtained. Further, when the boundary between the bottom and the sidewall is rounded, and the vertical MOSFET functions in a diode operation or in an avalanche operation, the current concentration at the boundary between the bottom and the sidewall is reduced. Accordingly, it is possible to provide the vertical MOSFET with high breakdown tolerance.

Here, when the atmospheric temperature of the CVD apparatus is high (for example, 1600° C. or higher) while forming the P type channel layer 3a, the boundary between the bottom and the sidewall of the contact trench 3c has a rounded shape.

### Other Embodiments

The present disclosure is not limited to the above described embodiments. The present disclosure is changeable appropriately.

For example, in the above embodiments, SiC is used as the semiconductor material. Alternatively, the present disclosure is applicable to the semiconductor device made of other semiconductor materials such as silicon in addition to SiC. Here, in case of SiC, the drain voltage is ten times higher than the silicon device, and the breakdown electric field strength is large. Thus, it is necessary to form the P type deep layer 3b at a deeper position. Further, in case of SiC, the material is very hard, and therefore, it is difficult to form the P type deep layer 3b by the ion implantation process. Thus, a method for forming the P type deep layer 3b by epitaxially growing in the concavity 2a is effective. Accordingly, in case of SiC where it is required to form the P type deep layer 3b by the epitaxial growth, it is preferable to apply the present disclosure. When silicon is used as the semiconductor material, the thermal diffusion of the impurity is easier than SiC. Thus, at the step for forming the P type impurity layer 3, for example, a poly silicon film is deposited, and then, the P type impurity (e.g., boron) is diffused in a vapor phase, so that the P type impurity layer 3 may be formed.

In each embodiment, the formation step of the trench gate structure is performed before the formation step of the N+ type source region 4 and the P+ type contact region 5. Alternatively, these orders may be reversed.

Further, in the above described embodiments, multiple P type deep layers 3b are arranged to be separated from each other on a cross section in parallel to the surface of the substrate, i.e., cross sectional view of FIGS. 1 and 3. This shows that the P type deep layers 3b are separated from each other at least on the cross sectional views of FIGS. 1 and 3. Thus, the P type deep layers 3b may be partially connected to each other on a different cross sectional view. For example, when the trench gate structure has a stripe shape so that the trench gate structure extends along a direction perpendicular to the sheet of the drawing, the P type deep layer 3b has the structure with multiple parts, which are separated from each other. On the other hand, when the trench gate structure has a quadrangle shape, for example, and the P type deep layer 3b is arranged around the quadrangle shape, or when the P type deep layer 3b has a lattice shape, and the trench 6 has a stripe shape, the P type deep layers 3b are partially connected to each other on a cross sectional view different from FIGS. 1 and 3.

In each embodiment, the first conductive type is the N type, and the second conductive type is the P type, so that the N channel type vertical MOSFET is explained as an example. The conductive type of each part may be reversed, so that the present disclosure may be applied to the P channel type vertical MOSFET. Alternatively, in addition to the vertical MOSFET, the present disclosure may be applied to the IGBT. In case of IGBT, the conductive type of the SiC substrate is changed from the first conductive type to the second conductive type with respect to the vertical MOSFET. The conductive type of other parts may be the same as the vertical MOSFET.

1. A method for manufacturing a semiconductor device comprising:
forming a drift layer having a first conductive type with an impurity concentration lower than a semiconductor substrate on the semiconductor substrate having the first conductive type or a second conductive type;
forming a plurality of first concavities to be separated from each other on a cross section in parallel to a surface of the semiconductor substrate by removing a part of the drift layer in an etching process using a mask after the mask is arranged on a surface of the drift layer;
forming a second conductive type impurity layer for providing a plurality of deep layers having the second conductive type in the plurality of first concavities and for providing a channel layer having the second conductive type on the surface of the drift layer;
forming a trench gate structure by forming a trench between the plurality of deep layers to penetrate the channel layer from a surface of the second conductive type impurity layer, to reach the drift layer and to be shallower than the plurality of deep layers, by forming a gate insulation film on an inner surface of the trench, and by forming a gate electrode on the gate insulation film in the trench;
forming a source region having the first conductive type with a concentration higher than the drift layer by ion-implanting a first conductive type impurity in a surface portion of the channel layer;
forming a contact region having the second conductive type with a concentration higher than the channel layer by ion-implanting a second conductive type impurity in a surface portion of the channel layer corresponding to a center position of each first concavity;
forming a source electrode electrically connected to the source region and the contact region; and
forming a drain electrode on a back side of the semiconductor substrate, wherein:
in the forming of the second conductive type impurity layer, an epitaxial growth is performed under a growth condition that a contact trench provided by a recess is formed on a surface of a part of the second conductive type impurity layer corresponding to the center position of each first concavity; and
in the forming of the contact region, the contact region is formed on a bottom of the contact trench.

2. The method for manufacturing the semiconductor device according to claim 1, wherein:
a semiconductor material of the semiconductor substrate is silicon carbide; and
the drift layer and the second conductive type impurity layer are made of silicon carbide.

3. The method for manufacturing the semiconductor device according to claim 1, wherein:
in the forming of the second conductive type impurity layer, a part of the second conductive type impurity layer for providing the deep layer and another part of the second conductive type impurity layer for providing the channel layer are formed simultaneously by the epitaxial growth.

4. The method for manufacturing the semiconductor device according to claim 1, wherein:
when a part of the second conductive type impurity layer for providing the deep layer is formed, the part of the second conductive type impurity layer for providing the deep layer is formed to remain the recess deeper than the surface of the drift layer at a position corresponding to the center position of each first concavity; and
when another part of the second conductive type impurity layer for providing the channel layer is formed, the another part of the second conductive type impurity layer for providing the channel layer is formed on the surface of the drift layer including the recess to remain the contact trench on the surface of the channel layer.

5. The method for manufacturing the semiconductor device according to claim 1, wherein:
in the forming of the plurality of the first concavities using the mask, a second concavity is formed using the mask simultaneously at a position different from the first concavity;
in the forming of the second conductive type impurity layer, another recess remains as an alignment mark at a position corresponding to the second concavity; and
in each of the forming of the trench gate structure, the forming of the source region, and the forming of the contact region, a mask alignment is performed using the alignment mark.

6. The method for manufacturing the semiconductor device according to claim 1, wherein:
in the forming of the second conductive type impurity layer, the contact trench is formed to have a plurality of surfaces including a bottom and a sidewall.

7. The method for manufacturing the semiconductor device according to claim 6, wherein:
in the forming of the second conductive type impurity layer, the bottom of the contact trench is a flat surface.

8. The method for manufacturing the semiconductor device according to claim 6, wherein:
in the forming of the second conductive type impurity layer, the bottom or a boundary between the bottom and the sidewall of the contact trench has a rounded shape.

9. The method for manufacturing the semiconductor device according to claim 6, wherein:
in the forming of the second conductive type impurity layer, a vertical direction growth rate of the second conductive type impurity layer as a growth rate for forming a part of the second conductive type impurity layer formed on a bottom of each first concavity is larger than a lateral direction growth rate of the second conductive type impurity layer as a growth rate for forming another part of the second conductive type impurity layer formed on a sidewall of each first concavity.

10. The method for manufacturing the semiconductor device according to claim 1, wherein:
in the forming of the second conductive type impurity layer, a width of the contact trench along an alignment direction of the plurality of deep layers is smaller than a width of each first concavity along the alignment direction.
